(19) United States
(12) Patent Application Publication
(10) Pub. No.: US 2020/0272773 A1
(43) Pub. Date: Aug. 27, 2020

(54) PARAMETER DETERMINATION METHOD, PARAMETER DETERMINATION DEVICE, AND PARAMETER DETERMINATION PROGRAM

(71) Applicant: Mizuno Corporation, Osaka (JP)

(72) Inventors: Shin Hirai, Osaka (JP); Yudai Washida, Osaka (JP); Kazuki Urata, Osaka (JP); Yohei Yoshida, Osaka (JP)

(21) Appl. No.: 16/789,670

(22) Filed: Feb. 13, 2020

(30) Foreign Application Priority Data
Feb. 26, 2019 (JP) 2019032900

(51) Int. Cl. G06F 30/20; G06K 9/20

(52) U.S. Cl. CPC G06F 30/20; A43B 13/14; G06K 9/2054

(57) ABSTRACT

An information processor performs processing of: creating a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user; executing a simulation that applies a parameter to the simulation model and obtains, as a simulation result, data representing motions of the link model, with the parameters set to a plurality of values; and determining at least one parameter of the sole most suitable for the user out of the plurality of values based on the simulation result obtained in the executing the simulation.

### CROSS-REFERENCE TO RELATED APPLICATION

This application claims priority to Japanese Patent Application No. 2019-032900 filed on Feb. 26, 2019, the entire disclosure of which is incorporated by reference herein.

### BACKGROUND

The present disclosure relates to a technique of determining sole characteristics most suitable for a user.

U.S. Patent Application Publication No. 2007/0039209 discloses a technique of obtaining information such as the width of a foot of a user by scanning the foot of the standing and seated user, and determining characteristic parameters such as the width of an insole based on the obtained information such as the width of the foot.

### SUMMARY

However, there is a demand for determining, as sole characteristics most suitable for a user, an elastic parameter indicating the degree of elasticity of the sole, a viscosity parameter corresponding to the damping coefficient of the sole, and a thickness parameter corresponding to the thickness of the sole.

The elastic, viscosity, and thickness parameters most suitable for the user depend on, however, the motions of the user. It is thus difficult to accurately determine the parameters based only on the information on the foot in the stationary state obtained as described in U.S. Patent Application Publication No. 2007/0039209.

The present disclosure was made in view of the problem. It is an objective of the present disclosure to accurately determine at least one of the elastic parameter, viscosity parameter, or thickness parameter of a sole most suitable for a user.

In order to achieve the above objective, a first aspect of the present disclosure provides a parameter determination method including: creating a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user; executing a simulation that applies at least one parameter of an elastic parameter corresponding to a spring constant of the elastic elements, a viscosity parameter corresponding to a damping coefficient of the elastic elements, or a thickness parameter corresponding to a length of the elastic elements to the simulation model and obtains, as a simulation result, data representing motions of the link model, with the parameters set to a plurality of values; and determining the at least one parameter of the sole most suitable for the user out of the plurality of values based on the simulation result obtained in the executing the simulation. The creating the simulation model, the executing the simulation, and the determining the characteristics are performed by an information processor.

In this first aspect, the determined parameter(s) reflect(s) the motions of the user during the predetermined movement. This allows accurate determination on at least one of the elastic parameter, viscosity parameter, or thickness parameter of the sole most suitable for the user.

The simulation result is obtained simply by executing the simulation with at least one of the elastic parameter, viscosity parameter, or thickness parameter set to the plurality of values. This reduces the work and costs as compared to an experiment requiring the user to actually wear a plurality of types of soles with different values as the at least one of the parameters.

According to a second aspect, in the first aspect, the at least one parameter is the elastic parameter and the viscosity parameter.

This second aspect allows accurate determination on the elastic and viscosity parameters most suitable for the user, while reflecting the motions of the user during the predetermined movement.

According to a third aspect, in the first aspect, the plurality of measurement points include measurement points around and both front and rear of a metacarpophalangeal (MP) joint of the user.

The third aspect allows more accurate determination on the parameter(s) most suitable for the user, since the determined parameter(s) reflect(s) how the MP link bends.

According to a fourth aspect, the method of the first aspect further includes: imaging the user during the predetermined movement with markers attached to the plurality of measurement points of the body of the user, using an imaging system to obtain moving image data; and obtaining the measurement information using the information processor based on the moving image data obtained in the imaging. Only one point of the measurement points is located on an upper body of the user.

In fourth aspect, there is no need to attach two or more markers to the upper body of the user, which facilitates the measurement operation.

A fifth aspect provides a parameter determination system including: a model creator configured to create a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user; a simulation executor configured to execute a simulation that applies at least one parameter of an elastic parameter corresponding to a spring constant of the elastic elements, a viscosity parameter corresponding to a damping coefficient of the elastic elements, or a thickness parameter corresponding to a length of the elastic elements to the simulation model and obtains, as a simulation result, data representing motions of the link model, with the parameters set to a plurality of values; and a characteristic determiner configured to determine the at least one parameter of the sole most suitable for the user out of the plurality of values based on the simulation result obtained by the simulation executor.

In the fifth aspect, the determined parameter(s) reflect(s) the motions of the user during the predetermined movement. This allows accurate determination on at least one of the elastic parameter, viscosity parameter, or thickness parameter of the sole most suitable for the user.

The simulation result is obtained simply by executing the simulation with at least one of the elastic parameter, viscosity parameter, or thickness parameter set to the plurality of values. This reduces the work and costs as compared to an experiment requiring the user to actually wear a plurality of types of soles with different values as the at least one of the parameters.

A sixth aspect provides a non-transitory computer readable medium storing a parameter determination program that causes an information processor to execute: creating a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user; executing a simulation that applies at least one parameter of an elastic parameter corresponding to a spring constant of the elastic elements, a viscosity parameter corresponding to a damping coefficient of the elastic elements, or a thickness parameter corresponding to a length of the elastic elements to the simulation model and obtains, as a simulation result, data representing motions of the link model, with the parameters set to a plurality of values; and determining the at least one parameter of the sole most suitable for the user out of the plurality of values based on the simulation result obtained in the executing the simulation.

In the sixth aspect, the determined parameter(s) reflect(s) the motions of the user during the predetermined movement. This allows accurate determination on at least one of the elastic parameter, viscosity parameter, or thickness parameter of the sole most suitable for the user.

The simulation result is obtained simply by executing the simulation with at least one of the elastic parameter, viscosity parameter, or thickness parameter set to the plurality of values. This reduces the work and costs as compared to an experiment requiring the user to actually wear a plurality of types of soles with different values as the at least one of the parameters.

The present disclosure allows accurate determination on at least one of the elastic parameter, viscosity parameter, and thickness parameter of a sole most suitable for a user.

### BRIEF DESCRIPTION OF THE DRAWINGS

FIG. 1 is a diagram illustrating a configuration of a parameter determination system.

FIG. 2 is a flowchart showing a procedure for providing a user with shoes.

FIG. 3 is a flowchart showing a procedure for obtaining measurement information.

FIG. 4 is an example diagram illustrating measurement points on a sagittal plane.

FIG. 5 is a table exemplarily showing measurement information.

FIG. 6 is a flowchart showing a procedure for creating a simulation model.

FIGS. 7A to 7C are tables showing numerical data necessary for creating the simulation model. FIG. 7A shows the masses and moments of inertia of first to fifth segments.

FIG. 7B shows the lengths of first to eighth segments. FIG. 7C shows the coordinate of the body center of gravity in an initial posture on the sagittal plane, the counterclockwise angles of first to sixth segments in the initial posture from the x-axis on the sagittal plane, and the time change amounts of the counterclockwise angles of the first to sixth segments in the initial posture from the x-axis on the sagittal plane.

FIGS. 8A to 8C are tables showing numerical data necessary for creating the simulation model. FIG. 8A shows the coordinate of the body center of gravity on the sagittal plane at each predetermined elapsed time, and the counterclockwise angles of first to fifth segments from the x-axis. FIG. 8B shows the x- and y-components of the velocity of the body center of gravity on the sagittal plane at each predetermined elapsed time, and the time change amounts of the counterclockwise angles of the first to fifth segments from the x-axis. FIG. 8C shows the x- and y-components of the acceleration of the body center of gravity on the sagittal plane at each predetermined elapsed time, and the time change rates of the time change amounts of the counterclockwise angles of the first to fifth segments from the x-axis.

FIG. 9 illustrates a rigid link model M.

FIGS. 10A to 10C are graphs showing results of simulation performed with a spring constant and a damping coefficient set to values corresponding to the sole of a test shoe. FIG. 10A shows the case of an angle θ2. FIG. 10B shows the case of an angle θ3. FIG. 10C shows the case of an angle θ4.

FIG. 11 is a table exemplarily showing the spring constant, the damping coefficient, the velocities of the upper end of a first link when the heel lifts off and touches the ground, and the value of an objective function in each simulation.

FIGS. 12A and 12B are perspective views illustrating a procedure for bonding a frame member of a midsole to an outsole. FIG. 12A illustrates a state before the frame member is bonded to the outsole. FIG. 12B illustrates a state after the frame member has been bonded to the outsole.

FIGS. 13A and 13B are perspective views illustrating a procedure for bonding a forefoot member, a midfoot member, and a hindfoot member of the midsole to the outsole. FIG. 13A illustrates a state before the fore-, mid-, and hindfoot members are bonded to the outsole. FIG. 13B illustrates a state after the fore-, mid-, and hindfoot members have been bonded to the outsole.

FIGS. 14A and 14B are perspective views illustrating a procedure for adhering an upper to the midsole. FIG. 14A illustrates a state before the upper is adhered to the midsole. FIG. 14B illustrates a state after the upper has been adhered to the midsole.

### DETAILED DESCRIPTION

An embodiment of the present disclosure will now be described in detail with reference to the drawings.

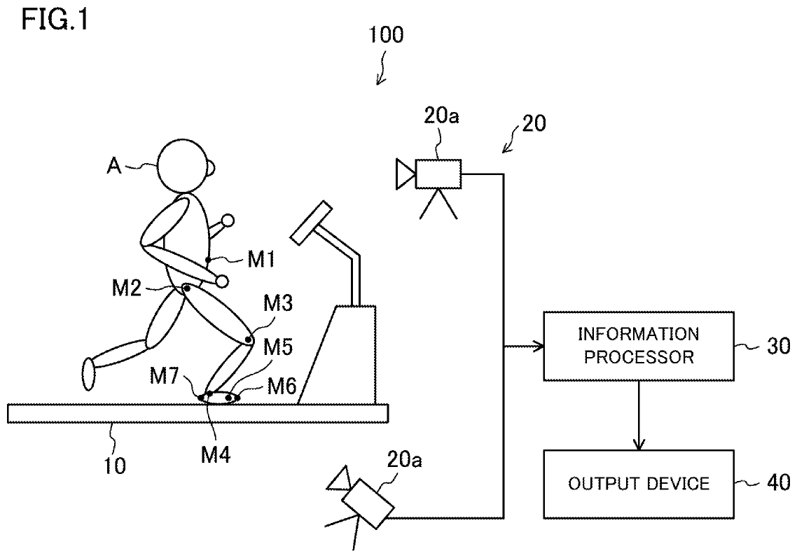

FIG. 1 shows a parameter determination system 100. This parameter determination system 100 includes a treadmill 10, an imaging system 20, an information processor 30, and an output device 40. The imaging system 20 images a user A running on the treadmill 10 with markers M1 to M7 attached. The information processor 30 serves as a parameter determination device according to the embodiment of the present disclosure, and determines the spring constant and the damping coefficient of a midsole 52, which will be described later, most suitable for the user A based on a moving image captured by the imaging system 20. The output device 40 outputs the spring constant and the damping coefficient which are determined by the information processor 30.

As shown in FIG. 1, the imaging system 20 may be a system including, for example, two high-speed cameras 20a and achieving a motion capture technique. The information processor 30 may be, for example, a personal computer (PC) including a central processing unit (CPU), a storage device, and software, for example. The output device 40 may be, for example, a monitor or a printer that visually outputs information. The output device 40 may output a test result using a method, such as voice, other than the visual sense, or a combination of two or more output methods such as audiovisual information.

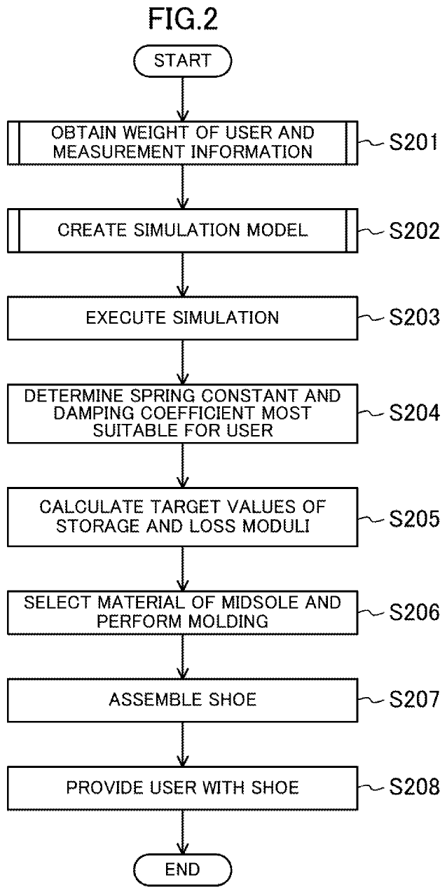

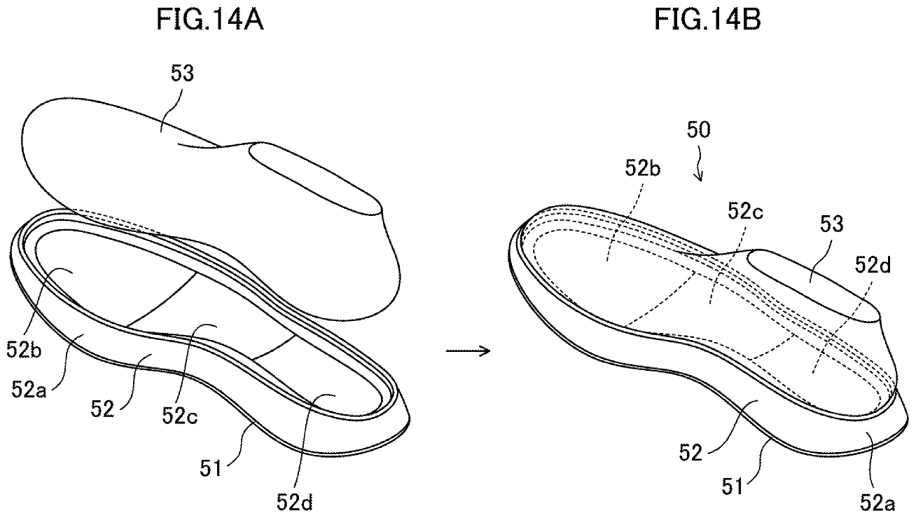

Next, a procedure for providing a shoe will be described with reference to a flowchart shown in FIG. 2. A provider provides the user A with a shoe 50 shown in FIG. 14B using the parameter determination system 100 configured as described above. In this procedure, the function of the information processor 30 is achieved by causing the CPU to execute programs recorded in a non-transitory computer readable medium such as an optical disk or a memory card, or programs downloaded via communication equipment. In this procedure, the information processor 30 functions as a model creator, a simulation executor, and a characteristic determiner.

The shoe 50 includes an outsole 51, a midsole 52, and an upper 53. The outsole 51 has a lower surface being a ground surface. The midsole 52 is adhered to the top of the outsole 51 and supports the sole surface of a wearer. The upper 53 is integrally adhered to the peripheral edge of the midsole 52 and covers a foot of the wearer from above and sides. The midsole 52 includes a frame member 52a, a forefoot member 52b, a midfoot member 52c, and a hindfoot member 52d. The frame member 52a serves as the outer periphery of the midsole 52. The fore-, mid-, and hindfoot members 52b, 52c, and 52d are fitted in this order inside the frame member 52a from the front.

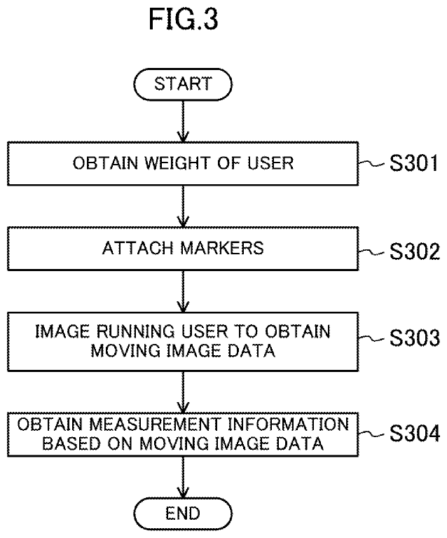

First, in Step (S) 201, the provider obtains information on the weight of the user A, and measures the motions of the body of the running user A at a plurality of measurement points to obtain measurement information. Specifically, as shown in FIG. 3, in Step 301, the provider measures the weight of the user A on the scales to obtain the weight of the user A. Note that the weight may not be measured but told by the user A.

Next, in Step 302, the provider attaches the markers M1 to M7 to the plurality of measurement points, specifically the periphery of the navel (abdomen), the right trochanter, the outside of the center of the right knee joint, the outside of the center of the right ankle joint, the outside of the metacarpophalangeal (MP) joint of the right foot, the right toe, and the right heel of the user A. Instead, the user A may attach the markers M1 to M7 by him/herself. In this manner, only one point of the measurement points is located on the upper body of the user A and there is no need to attach two or more markers to the upper body of the user A, which facilitates the measurement operation.

Then, in Step 303, the provider causes the user A to wear test shoes and to run on the treadmill 10 at his/her usual running speed. In this state, the imaging system 20 images the user A. Here, the soles of the test shoes may be formed by bonding a rubber with a uniform thickness bonded onto the bottom of the midsole with a uniform thickness. The obtained moving image data is output to the information processor 30.

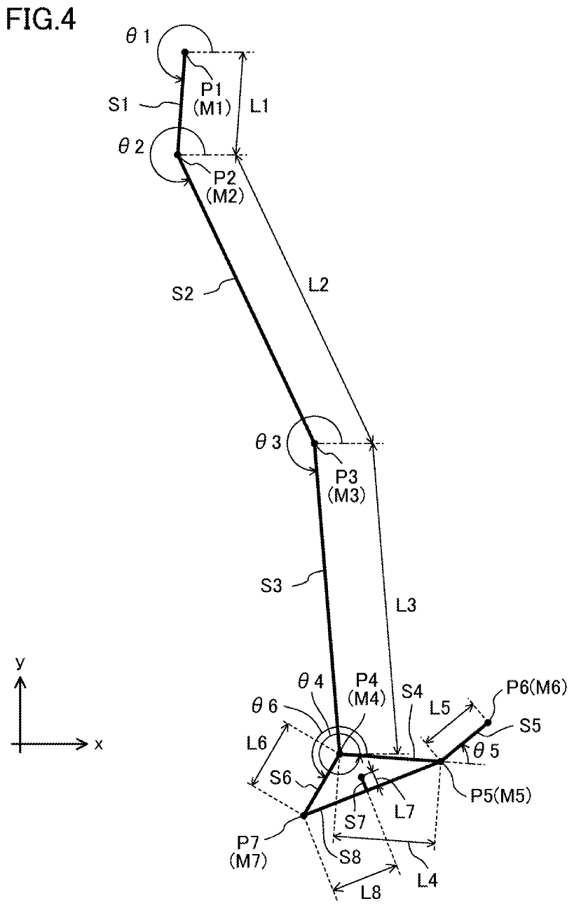

After that, in Step 304, the information processor 30 obtains, as the measurement information, the coordinates of the markers M1 to M7 (i.e., at measurement points P1 to P7) on the sagittal plane at each predetermined elapsed time from when the heel touches the ground until when the heel lifts off the ground based on the moving image data output from the imaging system 20. FIG. 4 is an example diagram showing the measurement points P1 to 7, to which the markers M1 to M7 are attached, on the sagittal plane. In this embodiment, the predetermined elapsed time is set to 0.002 seconds, but may have another value.

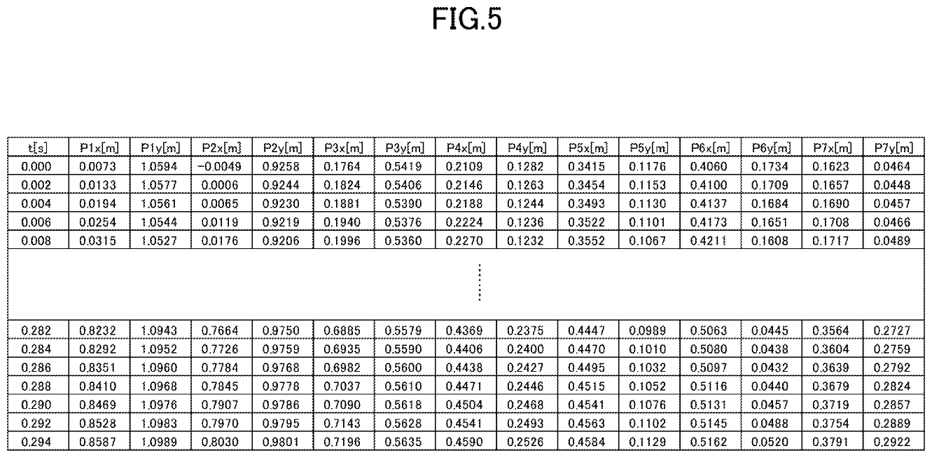

FIG. 5 shows example measurement information obtained in Step 304. Here, t indicates the elapsed time after the heel has touched the ground. P1x indicates the x-coordinate of the measurement point P1 on the sagittal plane. P1y indicates the y-coordinate of the measurement point P1 on the sagittal plane. Similarly, P2x to P7x sequentially indicate the x-coordinates of the measurement points P2 to P7 on the sagittal plane. P2y to P1y sequentially indicate the y-coordinates of the measurement points P2 to P7 on the sagittal plane.

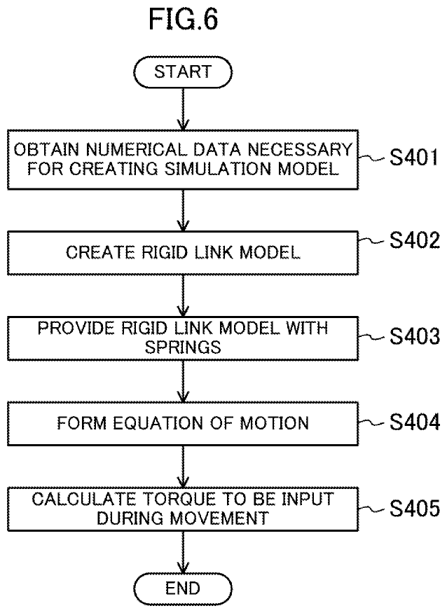

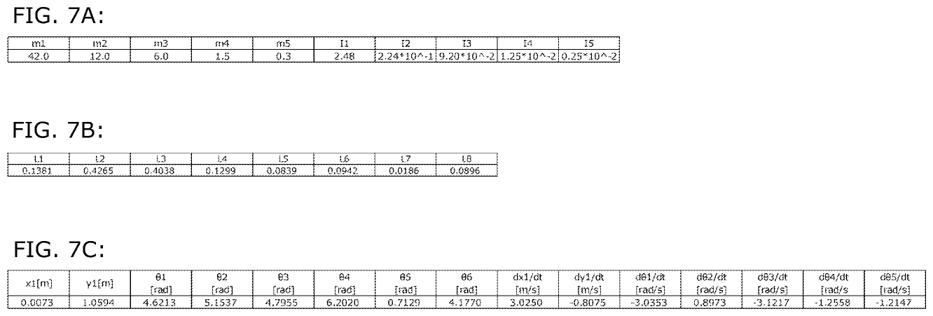

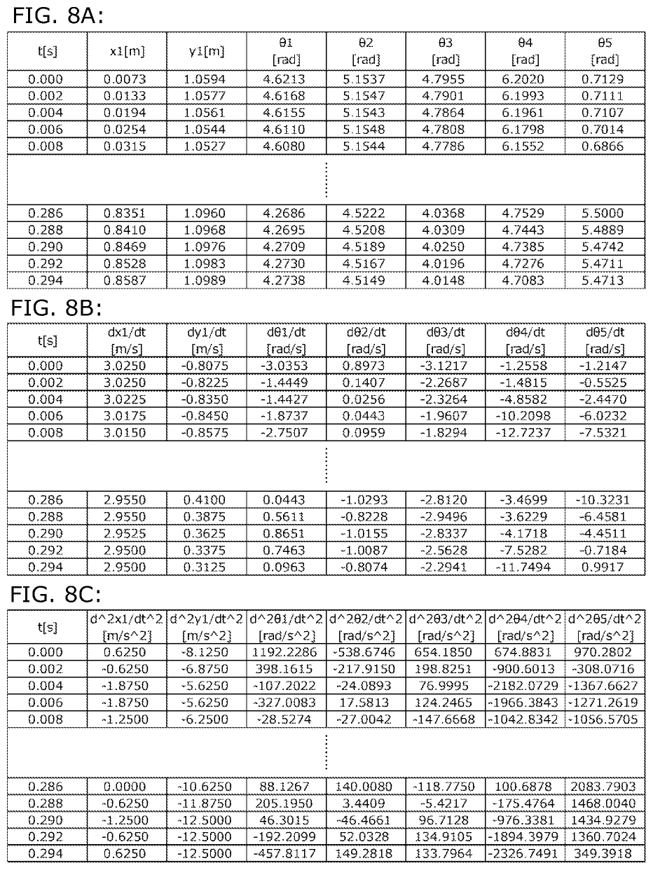

Next, in Step 202, the information processor 30 creates a simulation model based on the measurement information obtained in Step 201. Specifically, as shown in FIG. 6, first in Step 401, the information processor 30 obtains numerical data necessary for creating the simulation model based on the measurement information. FIGS. 7 and 8 exemplarily show the numerical data obtained in Step 401. Specifically, masses m1 to m5 and moments I1 to I5 of inertia of first to fifth segment S1 to S5, which will be described later, are calculated based on the weight of the user A obtained in Step 201. For calculation of the masses m1 to m5 and the moments I1 to I5, the method disclosed “ESTIMATION OF INERTIA PROPERTIES OF THE BODY SEGMENTS IN JAPANESE ATHLETES” A E et al., Society of Biomechanisms Japan (SOBIM), 1992 may be employed. The following are determined based on the measurement information obtained in Step 201: the coordinates x1 and y1 of the body center of gravity in an initial posture when the heel touches the ground on the sagittal plane, lengths L1 to L8 of first to eighth segments S1 to S8, which will be described later, counterclockwise angles θ1 to θ6 of first to sixth segments S1 to S6, which will be described later, in the initial posture from the x-axis (i.e., the horizontal axis) on the sagittal plane, and the time change amounts of these angles θ1 to θ5 in the initial posture. The following are also determined based on the measurement information obtained in Step 201: the coordinates x1 and y1 of the body center of gravity at each predetermined elapsed time, the x- and y-components of the velocity of the body center of gravity, the x- and y-components of the acceleration of the body center of gravity, the time change amounts (i.e., velocities) of the angles θ1 to θ5, and the time change rates (i.e., accelerations) of the time change amounts of the angles θ1 to θ5.

Here, the coordinate of the body center of gravity corresponds to the coordinate of the measurement point P1 at t=0, that is the vicinity of the navel (i.e., abdomen) of the user A, on the sagittal plane. The first segment S1 is, on the sagittal plane, represented by a line segment extending between the measurement point P1, that is, the vicinity of the navel (i.e., abdomen) and the measurement point P2, that is, the right trochanter of the user A. The second segment S2 is, on the sagittal plane, represented by a line segment extending between the measurement point P2 and the measurement point P3, that is, the outside of the center of the right knee joint. The third segment S3 is, on the sagittal plane, represented by a line segment extending between the measurement point P3 and the measurement point P4, that is, the outside of the center of the right ankle joint. The fourth segment S4 is, on the sagittal plane, represented by a line segment extending between the measurement point P4 and the measurement point P5, that is, the outside of the MP joint of the right foot. The fifth segment S5 is, on the sagittal plane, represented by a line segment extending between the measurement point P5 and the measurement point P6, that is, the right toe. The sixth segment S6 is, on the sagittal plane, represented by a line segment extending between the measurement point P4 and the measurement point P7, that is, the right heel. The seventh segment S7 is, on the sagittal plane, represented by a line segment extending from the center of gravity G among the measurement points P4, P5, and P7 perpendicularly to a line segment L extending between the measurement points P5 and P7. The eighth segment is, on the sagittal plane, represented by a line segment extending between the measurement point P7 and the intersection between the seventh segment S7 and the line segment L. The angles θ1 to θ6 sequentially represent the counterclockwise angles of the first to sixth segments from the x-axis (i.e., the horizontal axis) on the sagittal plane.

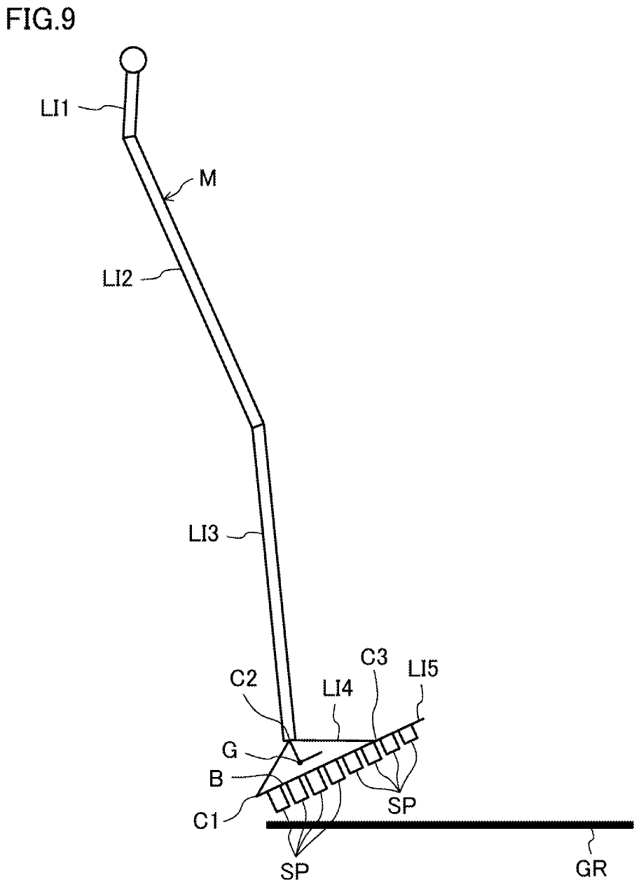

Next, in Step 402, the information processor 30 creates a rigid link model M on the sagittal plane, as shown in FIG. 9. In FIG. 9, GR represents a floor surface. The rigid link model M is formed by connecting the first to fifth links LI1 to LI5. The first link LI1 corresponds to the upper body (e.g., head, arms, and trunk (HAT)). The second link LI2 corresponds to a thigh. The third link LI3 corresponds to a lower leg. The fourth link LI4 corresponds to a foot. The fifth link LI5 corresponds to a toe. One end of the first link LI1 is connected to (positionally constrained by) one end of the second link LI2. The other end of the second link LI2 is connected to (positionally constrained by) one end of the third link LI3. The other end of the third link LI3 is connected to (positionally constrained by) one end of the fourth link LI4. The other end of the fourth link LI4 is connected to (positionally constrained by) one end of the fifth link LI5.

The length, mass, and moment of inertia of the first link LI1 are set to the length L1, the mass m1, and the moment I1 of inertia of the first segment S1, respectively. The center of gravity of the first link LI1 is defined to be positioned at the end not connected to the second link LI2, that is, the upper end.

The length, mass, and moment of inertia of the second link LI2 are set to the length L2, the mass m2, and the moment I2 of inertia of the second segment S2, respectively. The center of gravity of the second link LI2 is defined to be positioned at the midpoint thereof.

The length, mass, and moment of inertia of the third link LI3 are set to the length L3, mass m3, and moment I3 of inertia of the third segment S3, respectively. The center of gravity of the third link LI3 is defined to be positioned at the midpoint thereof.

The length, mass, and moment of inertia of the fourth link LI4 are set to the length L4, mass m4, and moment I4 of inertia of the fourth segment S4, respectively. The center of gravity G of the fourth link LI4 is defined to be the center gravity among coordinates C1 to C3. The coordinate C1 corresponds to the right heel. The coordinate C2 corresponds to the center of the right ankle joint. The coordinate C3 corresponds to the MP joint of the right foot. The coordinate C2 corresponds to the one end of the fourth link LI4. The coordinate C3 corresponds to the other end of the fourth link LI4. The coordinate C1 can be obtained based on the coordinate C2 and the length L6 and angle θ6 of the sixth segment S6.

The length, mass, and moment of inertia of the fifth link LIS are set to the length L5, the mass m5, and the moment IS of inertia of the fifth segment S5, respectively. The center of gravity of the fifth link LI5 is defined to be positioned at a midpoint thereof.

Then, in Step 403, the rigid link model M created in Step 402 is provided with eight springs SP as viscoelastic elements on the sole at equal intervals in the longitudinal direction so as to expand and contract perpendicularly to the sole. The sole corresponds to a line segment B extending between the coordinates C1 and C3. The natural length of the springs SP is set to 20 mm. While expanding and contracting perpendicularly to the sole, the springs SP may expand and contract to be inclined from the sole. The springs SP may be at least deformable perpendicularly to the sole.

After that, in Step 404, an equation of motion when the force of gravity and the eight springs SP act on the rigid link model M created in Step 402 is formed. In the equation of motion, inputs are joint torques acting on the joints (i.e., connecting points between the links LI1 to LI5), whereas the solutions are the counterclockwise angles θ1 to θ5 of the links LI1 to LI5 from the x-axis (i.e., the horizontal axis) on the sagittal plane. At this time, it is assumed that the force of gravity acts on the centers of gravity of the links LI1 to LIS. At time t, the force fᵢ(t) represented by the following Equation (1) acts on the sole from each spring. In Equation (1), i represents the ordinal number of the spring counting from the front of the sole, kᵢ represents the spring constant of the i-th spring from the front of the sole, c represents the damping coefficient of the springs, xᵢ(t) represents the length of the i-th spring from the front of the sole, and xᵢ(0) represents the initial length of the i-th spring from the front of the sole.

[Math. 1]

fᵢ(t)=−kᵢ(xᵢ(t)−xᵢ(0)−c\dot{x}ᵢ(t) (Equation 1)

The equation of motion is formed as follows. When a spring comes into contact with the floor surface, that is, when the y-coordinate of the tip (the end opposite to the sole) of the spring is 0, friction acts between the spring and the floor surface in contact with the spring. When the angles of the joints exceed a movable range of the joints of a human, that is, when the angles θ1 to θ5 come out of the predetermined numerical range, reaction force acts. The information processor 30 may perform the processing of Steps 402 to 404 using Altair MotionSolve manufactured by Altair Engineering, Inc.

Next, in Step 405, the system represented by the equation of motion formed in Step 404 is subjected to PD (Proportional Derivative) control to determine the torque to be input at each time. The spring constant k and the damping coefficient c here are set to the values associated with the midsole of the test shoe.

The torque Ti(t) to input at each time is expressed by the following Equation (2). In Equation (2), Kₚ represents a proportional gain, K_{D} represents a differential gain, i represents the ordinal number of the link, θ_{i_}sim(t) represents the angle θᵢ at the time t calculated from the equation of motion formed in Step 404, and θ_{_}exp(t) is the angle θᵢ of the numerical data obtained in Step 401.

[Math. 2]

Tᵢ(t)=−K_{P}(θ_{i_}sim(t)−θ_{i_}exp(t))−K_{D}θ_{_}sim(t) (Equation 2)

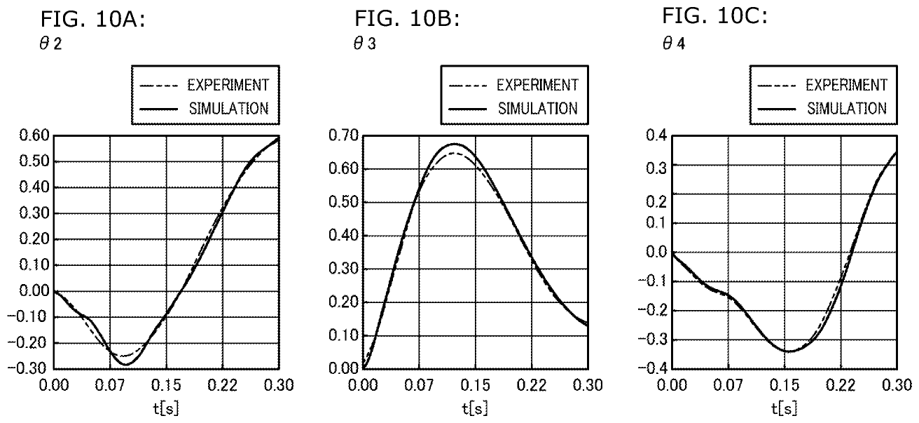

With the spring constant k and damping coefficient c set to the values associated with the midsole of the test shoe, the torque to be input, which has been determined in Step 405, is input to the equation of motion formed in Step 404. The calculated angles θ2 to θ4 (indicated by solid lines in FIG. 10) follow the numerical data (indicated by the imaginary lines in FIG. 10) obtained in Step 401 based on the measurement information as shown in FIG. 10.

The torque to be input, which has been determined in Step 405, is input to the equation of motion given in Step 404, which is a simulation model of the movement of the user A.

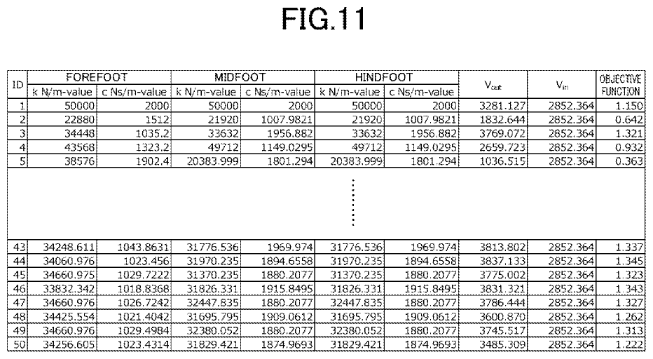

Then, in Step 203, the information processor 30 executes simulations that apply a predetermined spring constant k and a predetermined damping coefficient c to the simulation model created in Step 202. At this time, the spring constant k and the damping coefficient c may be set to those in a plurality of combinations shown in FIG. 11. The information processor 30 obtains then, as simulation results, data representing the movement of the rigid link model M, specifically, the coordinate of the upper end of the first link LH at each time and records the obtained data. The spring constant k is set to a plurality of values based on a global response surface method (GRSM). In this manner, the simulation results are obtained simply by executing the simulations with the spring constant k and the damping coefficient c set to those in the plurality of combination. This reduces the work and costs as compared to an experiment requiring the user to actually wear a plurality of types of midsoles with different spring constants k and damping coefficients c. The information processor 30 may perform the processing of Step 405 of Step 202 using Altair Activate manufactured by Altair Engineering, Inc. On the other hand, the information processor 30 may perform the processing of Step 203 using AltairHyperStudy manufactured by Altair Engineering, Inc.

Next, in Step 204, the information processor 30 calculates the objective function based on the simulation results obtained by the simulations in Step 203. The objective function has the following Value (1). Here, vₒᵤₜ is the velocity of the upper end of the first link LI1 when the heel lifts off the ground, whereas vᵢₙ is the velocity of the upper end of the first link LI1 when the heel touches the ground.

[Math. 3]

vₒᵤₜ/vᵢₙ (Value 1)

The information processor 30 determines then the combination providing the maximum objective function as the spring constant k and damping coefficient c most suitable for the user A, and causes the output device 40 to output the combination. In this manner, the determined spring constant k and damping coefficient c reflect the motions of the running user.

This allows accurate determination on the spring constant k and damping coefficient c of the midsole 52 most suitable for the user. In addition, the measurement points P4 to P7 are located around and on both front and rear of the MP joint. This causes the determined spring constant k and damping coefficient c to reflect how the MP joint bends. This allows more accurate determination on the spring constant k and damping coefficient c most suitable for the user A than in the case not reflecting how the MP joint bends.

After that, in Step 205, the shoe provider refers to the spring constant k and the damping coefficient c output from the output device 40 to calculate target values of a storage modulus and a loss modulus for a dynamic viscoelasticity test. The storage modulus E′ is represented by the following Equation (3), whereas the loss modulus E″ is represented by the following Equation (4). In Equations (3) and (4), i represents a number for identifying three parts constituting the midsole 52. No. 1 denotes the forefoot member 52b, 2 denotes the midfoot member 52c, and 3 denotes the hindfoot member 52d. S1 represents the projected area when the parts are viewed from above, lᵢ represents the length obtained by dividing the volume of the parts by Sᵢ, kᵢ represents the spring constant k most suitable for the user A determined in Step 204, cᵢ represents the damping coefficient c most suitable for the user A determined in Step 204, and ω represents the frequency at the dynamic viscoelasticity test.

$$\begin{matrix}[ Math . 4 ] & \\ {E}^{′} = \frac{{l}_{i}}{{S}_{i}} {k}_{i} & ( Equation 3 ) \\ [ Math . 5 ] & \\ {E}^{″} = \frac{{l}_{i}}{{S}_{i}} ω {c}_{i} & ( Equation 4 )\end{matrix}$$

In Step 206, the shoe provider selects a material that matches the target values of the storage and loss moduli calculated in Step 205. Using the selected material, the shoe provider molds the forefoot member 52b, the midfoot member 52c, and the hindfoot member 52d.

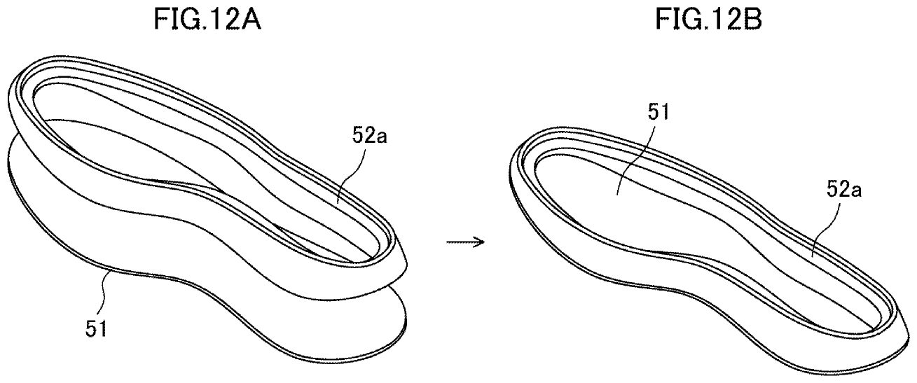

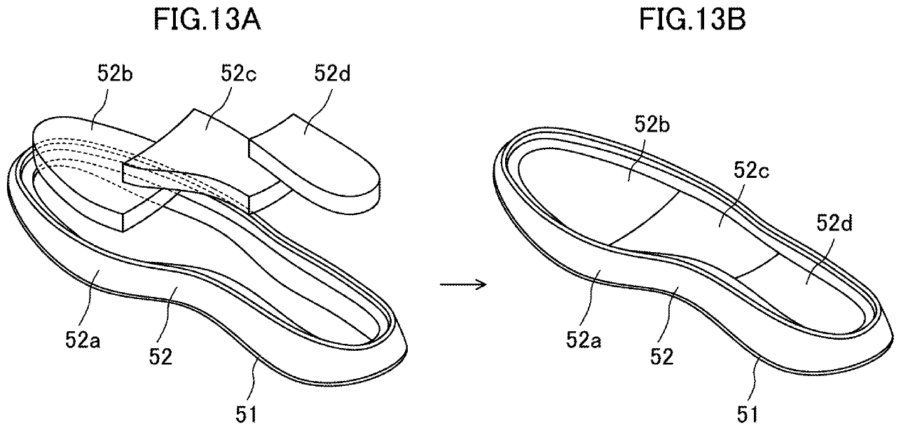

Then, in Step 207, as shown in FIG. 12, the shoe provider adheres the frame member 52a of the midsole 52 to the outer periphery of the outsole 51. After that, as shown in FIG. 13, the shoe provider fits the fore-, mid-, and hindfoot members 52b, 52c, and 52d inside the frame member 52a of the midsole 52 and adheres the members to the upper surface of the outsole 51. Finally, as shown in FIG. 14, the shoe provider adheres the upper 53 to the frame member 52a of the midsole 52, whereby the shoe 50 is completed.

In Step 208, the shoe provider provides the user A with the shoe 50 completed in Step 207.

In the embodiment described above, the information processor 30 determines the spring constant k and the damping coefficient c. Alternatively, the information processor 30 may determine an elastic parameter corresponding to the spring constant k instead of the spring constant k, or a damping parameter corresponding to the damping coefficient c instead of the damping coefficient c. The information processor 30 may create a simulation model using one of the spring constant k and the damping coefficient c as a constant and determine only the other of the spring constant k and the damping coefficient c.

While running in Step 303 in the embodiment described above, the user A may perform predetermined movement such as walking or jumping instead of running, depending on the purpose of the shoes to be provided. If shoes for long-distance running are provided, the user may run at a relatively low speed in Step 303. If the shoes for sprint are provided, the user may run at a relatively high speed in Step 303.

While the torque to be input to the simulation model at each time is determined by the PD control in Step 405, the torque to be input may be determined by another type of feedback control.

In the embodiment described above, the objective function calculated in Step 204 has Value (1), that is, the ratio of the velocity of the upper end of the first link LI1 when the heel lifts off the ground to the velocity of the upper end of the first link LI1 when the heel touches the ground. Alternatively, the objective function may have the following Value (2). Employment of Value (1) or (2) as the objective function provides the shoe 50 that allows efficient movement.

[Math. 6]

m(vₒᵤₜ²−vᵢₙ²)/2Δt (Value 2)

The objective function calculated in Step 204 may have the following Value (3) or (4). Here, F₁ₛₜₚₑₐₖ represents the value of the y-coordinate of the first peak of the waveform of the graph in which the y-axis represents the total force acting on the eight springs and the x-axis represents the time elapsed after the start of simulation. On the other hand, t₁ₛₜₚₑₐₖ represents the value of the x-coordinate of the first peak of the waveform of the graph. Here, F_{2ndpeak} represents the value of the y-coordinate of the second peak of the waveform of the graph in which the y-axis represents the total force acting on the eight springs and the x-axis represents the time elapsed after the start of simulation. Employment of Value (3) or (4) as the objective function provides the shoe 50 that allows the user to run at a lower load.

[Math. 7]

F₁ₛₜₚₑₐₖ/t₁ₛₜₚₑₐₖ (Value 3)

F_{2ndpeak} (Value 4)

The objective function calculated in Step 204 may have the following Value (5). Here, v_{y out} is the y-component of the velocity of the upper end of the first link LI1 when the heel lifts off the ground. Employment of Value (5) as the objective function provides the shoe 50 that allows the user to feel like floating.

[Math. 8]

v_{y out} (Value 5)

The objective function calculated in Step 204 may have a value based on some of Values (1) to (5), for example, a value obtained by weighting some of Values (1) to (5) and adding the weighting result.

In the embodiment described above, the information processor 30 determines the spring constant k and the damping coefficient c most suitable for the user using the simulation model where the natural length of the springs SP is a constant of 20 mm, and the spring constant k and the damping coefficient c are variables. Alternatively, the information processor 30 may use a simulation model where the natural length of the springs SP or the length of the springs SP upon receipt of a predetermined load is a variable and the spring constant k and the damping coefficient c are constants. The information processor 30 determines, as a thickness parameter, the natural length of the springs SP or the length of the springs SP upon receipt of a predetermined load that is suitable for the user. This allows the shoe provider to determine the thicknesses of the midsole 52 and outsole 51 most suitable for the user A by referring to the determined thickness parameter.

In the embodiment described above, in Steps 205 and 206, the shoe provider selects the material of the midsole 52 based on the spring constant k and the damping coefficient c determined in Step 204. Alternatively, the shoe provider may select the shape (or the structure) of the midsole 52.

In the embodiment described above, the value of the spring constant k is set in Step 203 by the GRSM. Alternatively, the value may be set by another method such as genetic algorithm (GA) or multi-objective genetic algorithm (MOGA), for example.

In the embodiment described above, the present disclosure is applied to determination on the spring constant k and the damping coefficient c of the midsole 52. The present disclosure is also applicable to determination on the spring constant k and the damping coefficient c of the outsole 51.

The present disclosure is useful as a technique of determining sole characteristics most suitable for a user.

What is claimed is:

1. A parameter determination method, comprising:
creating a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user;
executing a simulation that applies at least one parameter of an elastic parameter corresponding to a spring constant of the elastic elements, a viscosity parameter corresponding to a damping coefficient of the elastic elements, or a thickness parameter corresponding to a length of the elastic elements to the simulation model and obtains, as a simulation result, data representing motions of the link model, with the parameters set to a plurality of values; and
determining the at least one parameter of the sole most suitable for the user out of the plurality of values based on the simulation result obtained in the executing the simulation, wherein
the creating the simulation model, the executing the simulation, and the determining the characteristics are performed by an information processor.

2. The method of claim 1, wherein
the at least one parameter is the elastic parameter and the viscosity parameter.

3. The method of claim 1, wherein
the plurality of measurement points include measurement points around and both front and rear of a metacarpophalangeal (MP) joint of the user.

4. The method of claim 1, further comprising:
imaging the user during the predetermined movement with markers attached to the plurality of measurement points of the body of the user, using an imaging system to obtain moving image data; and
obtaining the measurement information using the information processor based on the moving image data obtained in the imaging; wherein
only one point of the measurement points is located on an upper body of the user.

5. A parameter determination device, comprising:
a model creator configured to create a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user;
a simulation executor configured to execute a simulation that applies at least one parameter of an elastic parameter corresponding to a spring constant of the elastic elements, a viscosity parameter corresponding to a damping coefficient of the elastic elements, or a thickness parameter corresponding to a length of the elastic elements to the simulation model and obtains, as a simulation result, data representing motions of the link model, with the parameters set to a plurality of values; and
a characteristic determiner configured to determine the at least one parameter of the sole most suitable for the user out of the plurality of values based on the simulation result obtained by the simulation executor.

6. A non-transitory computer readable medium storing a parameter determination program that causes an information processor to execute:
creating a simulation model using a link model including a plurality of links connected to each other and, on a sole, elastic elements deformable perpendicularly to the sole, based on a weight of a user and measurement information obtained by measuring motions of a body of the user at a plurality of measurement points during predetermined movement of the user;
executing a simulation that applies at least one parameter of an elastic parameter corresponding to a spring constant of the elastic elements, a viscosity parameter corresponding to a damping coefficient of the elastic elements, or a thickness parameter corresponding to a length of the elastic elements to the simulation model and obtains, as a simulation result, data representing motions of the link model, with the parameters set to a plurality of values; and
determining the at least one parameter of the sole most suitable for the user out of the plurality of values based on the simulation result obtained in the executing the simulation.
